(19) United States
(12) Patent Application Publication
(10) Pub. No.: US 2013/0168714 A1
(43) Pub. Date: Jul. 4, 2013

(54) LIGHT EMITTING DIODE PACKAGE STRUCTURE

(71) Applicants: Chao-Wei Li, Hsinchu City (TW); Hung-Lieh Hu, Hsinchu City (TW)

(72) Inventors: Chao-Wei Li, Hsinchu City (TW); Hung-Lieh Hu, Hsinchu City (TW)

(21) Appl. No.: 13/633,878

(22) Filed: Oct. 3, 2012

(30) Foreign Application Priority Data
Dec. 30, 2011 (TW) 100149880

(51) Int. Cl. H01L 33/52; H01L 33/50

(52) U.S. Cl. 257/98; 257/E33.06

(57) ABSTRACT

A light emitting diode package structure is provided, including a substrate, a seal assembly, an optical element, at least one light emitting diode chip, and a packaging material layer. The seal assembly is disposed on the substrate. The optical element is disposed on the seal assembly, and an enclosed space is formed between the optical element, the seal assembly, and the substrate. The light emitting diode chip is disposed on the substrate and located in the enclosed space. The packaging material layer is located in the enclosed space and at least disposed on an upper surface of the light emitting diode chip, wherein the packaging material layer includes a liquid with high viscosity and a plurality of solid particles, and the viscosity of the liquid with high viscosity is more than 3000 mPa·s.

### CROSS-REFERENCE TO RELATED APPLICATION

This application claims the priority benefit of Taiwan application serial no. 100149880, filed on Dec. 30, 2011. The entirety of the above-mentioned patent application is hereby incorporated by reference herein and made a part of this specification.

### TECHNICAL FIELD

The disclosure relates to a package structure, and particularly relates to a light emitting diode (LED) package structure.

### BACKGROUND

A light emitting diode (LED) is a light emitting device fabricated by using a compound semiconductor. When a current is applied to the LED, energy mat be released in the form of light through the combination of electron and electron hole, such that the LED can emit light. Since the light emitting phenomenon of LED is not caused by heating or discharging, the lifespan of LED may be more than 100,000 hours, and idling time is saved. In addition, LED has the advantages of high response speed, low power consumption, low pollution, high reliability, being suitable for mass production and so on. Accordingly, LED is widely applied in many fields. In recent years, luminescence efficiency of LED has been constantly improved. Consequently, fluorescent lamps and incandescent bulbs are gradually replaced with LED in some areas, such as scanner light source which requires high speed response, back or front light source of liquid crystal display (LCD), automobile dashboard illumination, traffic signs, and general illumination devices.

Generally, the color of the light emitted by the conventional LED is changed through conversion of the phosphor mixed with silicone (for example, the light generated by blue light LED irradiates yellow phosphor to generate white light). Silicone has favorable heat resistance and reliability when not mixed with phosphor. However, when silicone is mixed with phosphor to form a phosphor glue, the poor heat resistance of phosphor glue may seriously affect the reliability of the LED package structure. Therefore, it is a very important issue to develop a more suitable LED package material and structure for improving the reliability of LED light source module.

### SUMMARY

Accordingly, the disclosure provides a light emitting diode package structure, which may improve the poor heat resistance of the phosphor glue material used in the conventional light emitting diode package structure and may enhance the reliability of a light emitting diode light source module.

The disclosure provides a light emitting diode package structure, including a substrate, a seal assembly, an optical element, at least one light emitting diode chip, and a packaging material layer. The seal assembly is disposed on the substrate. The optical element is disposed on the seal assembly, and an enclosed space is formed between the optical element, the seal assembly, and the substrate. The light emitting diode chip is disposed on the substrate and located in the enclosed space. The packaging material layer is located in the enclosed space and at least disposed on an upper surface of the light emitting diode chip, wherein the packaging material layer includes a liquid with high viscosity and a plurality of solid particles, and the viscosity of the liquid with high viscosity is more than 3000 mPa·s.

The disclosure further provides a light emitting diode package structure, which includes a substrate, an optical element, at least one light emitting diode chip, and a packaging material layer. The substrate has a groove, and the light emitting diode chip is disposed on the substrate and located in the groove. The optical element is disposed on the substrate and encloses the groove, so as to form an enclosed space between the optical element and the substrate. The packaging material layer is located in the enclosed space and at least disposed on an upper surface of the light emitting diode chip, wherein the packaging material layer includes a liquid with high viscosity and a plurality of solid particles, and the viscosity of the liquid with high viscosity is more than 3000 mPa·s.

Several exemplary embodiments accompanied with figures are described in detail below to further describe the disclosure.

### BRIEF DESCRIPTION OF DRAWINGS

The accompanying drawings are included to provide further understanding, and are incorporated in and constitute a part of this specification. The drawings illustrate embodiments and, together with the description, serve to explain the principles of the disclosure.

FIG. 1 is a schematic cross-sectional view of a light emitting diode package structure according to an embodiment of the disclosure.

FIG. 2 is a schematic cross-sectional view of a light emitting diode package structure according to an embodiment of the disclosure.

FIG. 3 is a schematic cross-sectional view of a light emitting diode package structure according to an embodiment of the disclosure.

FIG. 4 is a schematic cross-sectional view of a light emitting diode package structure according to an embodiment of the disclosure.

FIG. 5 is a schematic cross-sectional view of a light emitting diode package structure according to an embodiment of the disclosure.

FIG. 6A illustrates a schematic cross-sectional view and a partial top view of a light emitting diode package structure according to an embodiment of the disclosure.

FIG. 6B is a schematic cross-sectional view of a light emitting diode package structure according to another embodiment of the disclosure.

FIG. 7 is a schematic cross-sectional view of a light emitting diode package structure according to an embodiment of the disclosure.

FIG. 8 illustrates a schematic cross-sectional view and a partial top view of a light emitting diode package structure according to an embodiment of the disclosure.

FIG. 9 is a schematic cross-sectional view of a light emitting diode package structure according to an embodiment of the disclosure.

### DETAILED DESCRIPTION OF DISCLOSED EMBODIMENTS

Embodiments of the disclosure will be fully described with reference to the accompanying drawings below. Nevertheless, the disclosure may be embodied in many different forms and should not be construed as limited to the embodiments set forth herein. The language used to describe the directions, such as “up” or the like, in the following embodiments simply refers to the directions of the drawings and is regarded in an illustrative rather than in a restrictive sense. It should be understood that, when a layer or component is described as being on another layer or component, it may mean that the layer or component is directly disposed on another layer or component or above another layer or component with a middle layer or component therebetween.

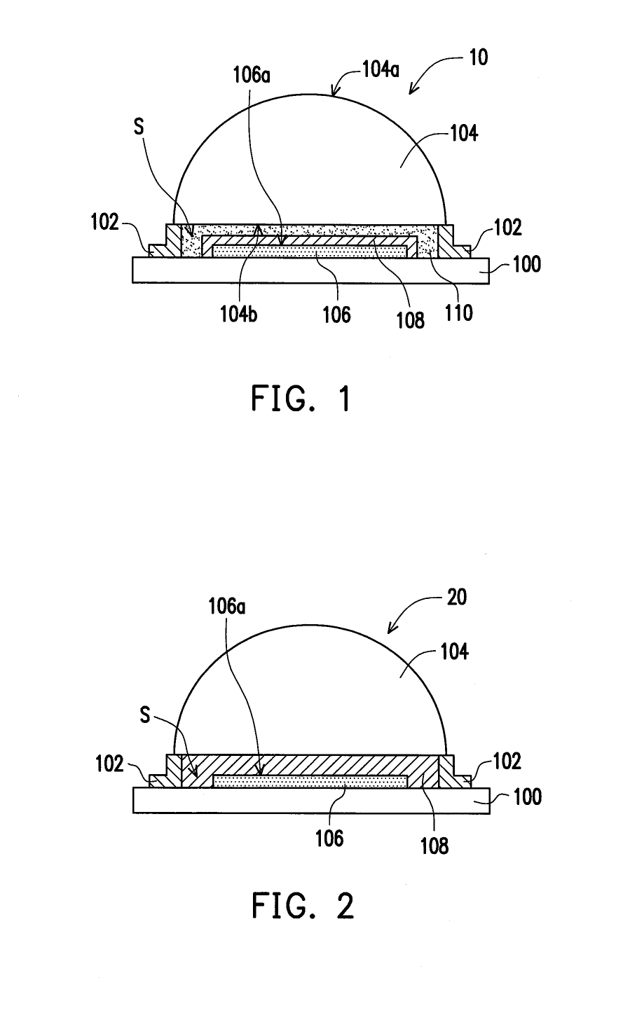

FIG. 1 is a schematic cross-sectional view of a light emitting diode package structure according to an embodiment of the disclosure. Referring to FIG. 1, a light emitting diode package structure 10 of the disclosure includes a substrate 100, a seal assembly 102, an optical element 104, at least one light emitting diode chip 106, a packaging material layer 108, and a filling material 110.

The substrate 100 is a Al₂O₃ substrate, a AlN substrate, a copper substrate, an aluminum substrate, a ceramic substrate, etc., for example.

The seal assembly 102 is disposed on the substrate 100. In an embodiment, the seal assembly 102 may be connected to a surface of the substrate 100 in the form of a barricade. A material of the seal assembly 102 is metal, plastic, alloy, wherein the alloy is kovar, for example.

The optical element 104 is disposed on the seal assembly 102, and an enclosed space S is formed between the optical element 104, the seal assembly 102, and the substrate 100. The optical element 104 has a curved convex surface 104a and a plane 104b, and the plane 104b is disposed on the seal assembly 102 and faces the substrate 100, so as to form the enclosed space S. However, the disclosure is not limited thereto. The optical element 104 may have other shapes, such as a planar plate shape. The optical element 104 is a lens, for example. Moreover, the optical element 104 is formed of a material with favorable light transmittance, such as glass, epoxy resin, or transparent plastic. Specifically, the transparent plastic is polypropylene, polyethylene, cyclic olefin copolymer, polymethylpentenes, hydrogenated cyclo-olefin polymers, or amorphous cyclo-olefin copolymers, for example.

The light emitting diode chip 106 is disposed on the substrate 100 and located in the enclosed space S. According to an embodiment, the light emitting diode chip 106 may be a high-power light emitting diode chip, which has a light emitting power more than 1 W.

The packaging material layer 108 is located in the enclosed space S. In this embodiment, the packaging material layer 108 is disposed on an upper surface 106a of the light emitting diode chip 106 and covers all exposed surfaces of the light emitting diode chip 106. More specifically, the packaging material layer 108 includes a liquid with high viscosity and a plurality of solid particles, and the viscosity of the liquid with high viscosity is more than 3000 mPa·s. The liquid with high viscosity is for example at least one selected from silicon oil, paraffin oil, olive oil, propylene carbonate, and perfluoropolyether solution. However, the disclosure is not limited thereto. Moreover, the solid particles are phosphor, TiO₂, ZrO₂, or Quantum Dot (QD), for example. Herein, the phosphor can be a single phosphor or a mixture of multiple phosphors. To be more specific, the Quantum Dot is a particle, such as ZnCdS QD or ZnCdSe QD, which has the characteristic of electroluminescence or light-luminescence and can be applied in the light emitting diode to achieve the properties of nearly continuous spectrum and high color rendering, etc.

It is noted that the disclosure is not limited to any particular combination of the liquid with high viscosity and the solid particles. For instance, when using phosphor as the solid particles, phosphor may be mixed with silicon oil and applied onto the light emitting diode chip 106 to cover the light emitting diode chip 106 by screen printing or barricade. Based on the above, a color of the light emitted by the light emitting diode chip 106 can be converted through the selected phosphor. Since the phosphor is mixed with the liquid with high viscosity, not with silicone, the use of phosphor glue does not cause poor heat resistance even when applied to the high-power light emitting diode chip.

The filling material 110 fills the enclosed space S. The filling material 110 is a liquid with favorable thermal conductivity, which is more than 0.55 W/m·K, for example. In addition, the filling material 110 is preferably fluid at room temperature, and the viscosity of the filling material 110 is less than the viscosity of the packaging material layer 108. More specifically, the filling material 110 is deionized water, electrolyzed water, or Fluorinert, for example. It is noted that, since the materials used for the filling material 110 and the packaging material layer 108 may be hydrophilic and lipophilic respectively, the filling material 110 and the packaging material layer 108 are not dissolvable to each other and can achieve liquid packaging.

Nevertheless, the filling material 110 of the disclosure is not limited to a liquid filling material. In other embodiments, the filling material 110 can be air, silicone, or epoxy resin, for example. For example, when using air as the filling material 110 (i.e. so-called hermetic packaging), because a mixture of the liquid with high viscosity and the solid particles in the packaging material layer 108 is not dissolvable to air, the packaging material layer 108 may remain in liquid state so as to form a liquid package structure.

Furthermore, in another embodiment, silicone or epoxy resin may be for example used as the filling material 110 to fill the enclosed space S and cover the packaging material layer 108. After the silicone or epoxy resin is baked, the mixture of the liquid with high viscosity and the solid particles in the packaging material layer 108 may remain in liquid state so as to form the light emitting diode package structure in an embodiment of the disclosure.

As described above, in this embodiment, the light emitting diode package structure is formed with better stability and heat resistance by mixing the stable and heat-resistant liquid with high viscosity and solid particles in the packaging material layer and selectively using the filling material that is not dissolvable to the packaging material layer. Accordingly, the problem of poor heat resistance of the phosphor glue used in the conventional package structure is improved, and the reliability of the light emitting diode light source module may be further enhanced. Moreover, since the disclosure uses the liquid with higher viscosity in the packaging material layer, the solid particles are uniformly distributed in the liquid with high viscosity, which prevents the problem that the solid particles having larger weight may deposit or be non-uniformly distributed due to a shake. Because the filling material 110 and the packaging material layer 108 are not dissolvable to each other, when the light emitting diode package structure 10 is shaken or vibrated, the packaging material layer 108 does not shift in position and provides better stability.

FIG. 2 is a schematic cross-sectional view of a light emitting diode package structure according to an embodiment of the disclosure. In FIG. 2, identical reference numerals are used for the same elements as those in FIG. 1, and descriptions of those elements are omitted.

Referring to FIG. 2, a light emitting diode package structure 20 of the disclosure includes a substrate 100, a seal assembly 102, an optical element 104, at least one light emitting diode chip 106, and a packaging material layer 108. Herein, the optical element 104 is disposed on the seal assembly 102, and an enclosed space S is formed between the optical element 104, the seal assembly 102, and the substrate 100. The light emitting diode chip 106 is disposed on the substrate 100 and located in the enclosed space S. The packaging material layer 108 is located in the enclosed space S, covers the light emitting diode chip 106, and fills the enclosed space S.

It should be noted that, the light emitting diode package structure 20 of this embodiment is similar to the light emitting diode package structure 10 of FIG. 1, and a difference lies in that: the light emitting diode package structure 20 of this embodiment does not include the filling material 110. In addition, the packaging material layer 108 is located in the enclosed space S and disposed on the upper surface 106a of the light emitting diode chip 106. The packaging material layer 108 covers the light emitting diode chip 106 and fills the enclosed space S.

In this embodiment, the packaging material layer 108 fills the enclosed space S, and thereby achieves liquid packaging. Herein, since the packaging material layer 108 includes the stable and heat-resistant liquid with high viscosity and solid particles, the light emitting diode package structure formed based on the above has better stability and heat resistance, and thus the reliability of the light emitting diode light source module may be improved.

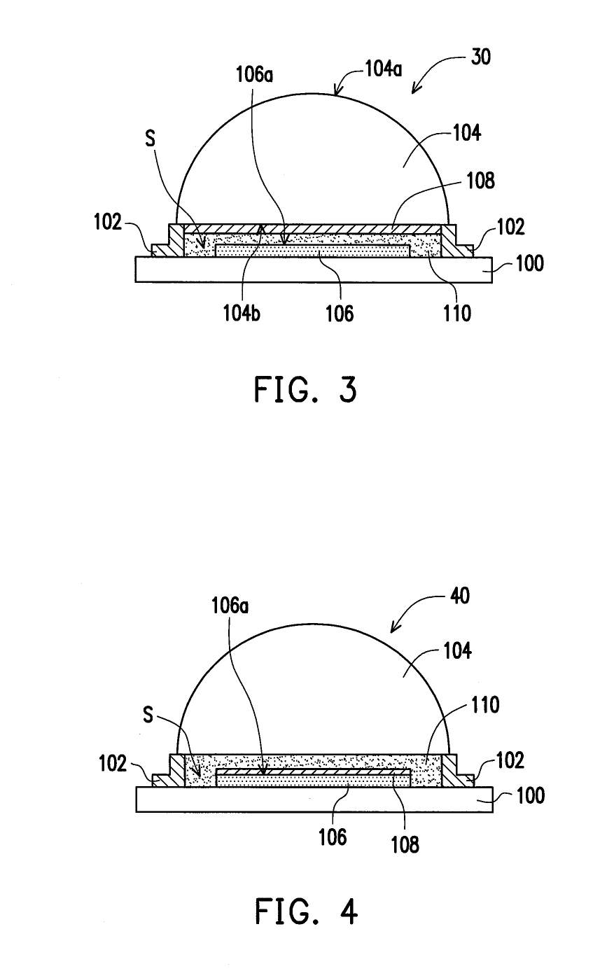

FIG. 3 is a schematic cross-sectional view of a light emitting diode package structure according to an embodiment of the disclosure. In FIG. 3, identical reference numerals are used for the same elements as those in FIG. 1, and descriptions of those elements are omitted.

Referring to FIG. 3, a light emitting diode package structure 30 of the disclosure includes a substrate 100, a seal assembly 102, an optical element 104, at least one light emitting diode chip 106, a packaging material layer 108, and a filling material 110. Herein, the optical element 104 is disposed on the seal assembly 102, and an enclosed space S is formed between the optical element 104, the seal assembly 102, and the substrate 100. The light emitting diode chip 106 is disposed on the substrate 100 and located in the enclosed space S.

It should be noted that, the light emitting diode package structure 30 of this embodiment is similar to the light emitting diode package structure 10 of FIG. 1, and a difference lies in that: although the packaging material layer 108 of this embodiment is disposed on the upper surface 106a of the light emitting diode chip 106, the packaging material layer 108 does not directly contact the light emitting diode chip 106. More specifically, as shown in FIG. 3, the packaging material layer 108 is disposed on a plane 104b of the optical element 104 and located in the enclosed space S. Moreover, the packaging material layer 108 is not in direct contact with the light emitting diode chip 106. The filling material 110 is for example disposed between the packaging material layer 108 and the light emitting diode chip 106, and fills the enclosed space S.

In this embodiment, the light emitting diode package structure of the disclosure is completed by disposing the packaging material layer 108 and the filling material 110, which are not dissolvable to each other, to fill the enclosed space S. Herein, since the packaging material layer 108 includes the stable and heat-resistant liquid with high viscosity and solid particles, the light emitting diode package structure formed based on the above has better stability and heat resistance, and thus the reliability of the light emitting diode light source module may be improved.

FIG. 4 is a schematic cross-sectional view of a light emitting diode package structure according to an embodiment of the disclosure. In FIG. 4, identical reference numerals are used for the same elements as those in FIG. 1, and descriptions of those elements are omitted.

Referring to FIG. 4, a light emitting diode package structure 40 of the disclosure includes a substrate 100, a seal assembly 102, an optical element 104, at least one light emitting diode chip 106, a packaging material layer 108, and a filling material 110. Herein, the optical element 104 is disposed on the seal assembly 102, and an enclosed space S is formed between the optical element 104, the seal assembly 102, and the substrate 100. The light emitting diode chip 106 is disposed on the substrate 100 and located in the enclosed space S.

The light emitting diode package structure 40 of this embodiment is similar to the light emitting diode package structure 10 of FIG. 1. However, in this embodiment, the light emitting diode chip 106 is for example a light emitting diode chip that has very good forward-direction luminescence efficiency (such as a vertically oriented light emitting diode chip), and the upper surface 106a is a main light emitting surface of the light emitting diode chip 106. In this case, the packaging material layer 108 may cover only the upper surface 106a and does not cover other surfaces of the light emitting diode chip 106. Besides, the filling material 110 fills the enclosed space S. Accordingly, the light generated by the light emitting diode chip 106 can still be emitted from the optical element through the packaging material layer 108 and the filling material 110.

Therefore, persons having ordinary skill in the art should know that, in the disclosure, the packaging material layer 108 and the filling material 110 can be disposed according to the light emitting properties of different light emitting diode chips, so as to form the light emitting diode package structure.

In this embodiment, the light emitting diode package structure of the disclosure is completed by disposing the packaging material layer 108 and the filling material 110, which are not dissolvable to each other, to fill the enclosed space S. Herein, since the packaging material layer 108 includes the stable and heat-resistant liquid with high viscosity and solid particles, the light emitting diode package structure formed based on the above has better stability and heat resistance, and thus the reliability of the light source module may be improved.

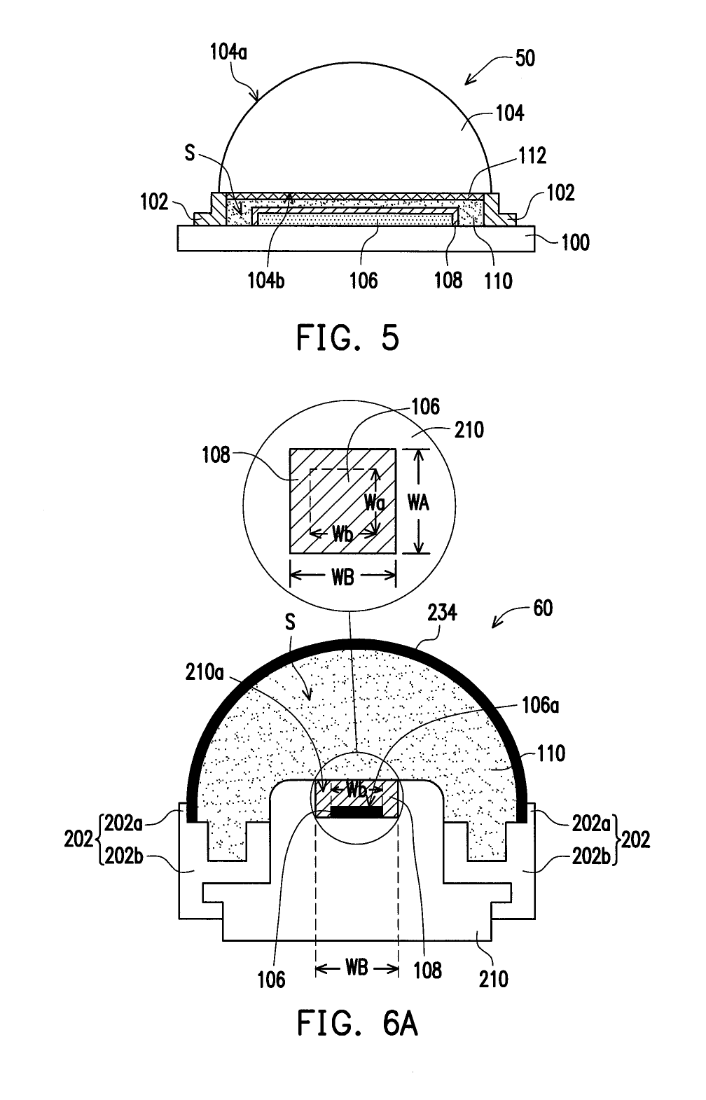

FIG. 5 is a schematic cross-sectional view of a light emitting diode package structure according to an embodiment of the disclosure. In FIG. 5, identical reference numerals are used for the same elements as those in FIG. 1, and descriptions of those elements are omitted.

Referring to FIG. 5, a light emitting diode package structure 50 of the disclosure includes a substrate 100, a seal assembly 102, an optical element 104, at least one light emitting diode chip 106, a packaging material layer 108, and a filling material 110. Herein, the optical element 104 is disposed on the seal assembly 102, and an enclosed space S is formed between the optical element 104, the seal assembly 102, and the substrate 100. The light emitting diode chip 106 is disposed on the substrate 100 and located in the enclosed space S. The packaging material layer 108 is disposed on the upper surface 106a of the light emitting diode chip 106 and located in the enclosed space S. Moreover, the packaging material layer 108 covers all exposed surfaces of the light emitting diode chip 106. Besides, the filling material 110 fills the enclosed space S.

It should be noted that, the light emitting diode package structure 50 of this embodiment is similar to the light emitting diode package structure 10 of FIG. 1, and a difference lies in that: the light emitting diode package structure 50 of this embodiment further includes a diffusion layer 112 disposed in the enclosed space S and located on a light emitting path of the light emitting diode chip 106. With reference to FIG. 5, specifically, the diffusion layer 112 is disposed on the plane 104b of the optical element 104, for example. However, the disclosure is not limited thereto. Persons with ordinary skill in the art should know that, in fact, the diffusion layer 112 may have various configurations.

The diffusion layer 112 is formed on the plane 104b of the optical element 104 by dispensing or spraying, for example. A material of the diffusion layer 112 includes nanoparticles of TiO₂, for example, but the disclosure is not limited thereto. In this embodiment, the diffusion layer 112 may be disposed to diffuse the light emitted from the light emitting diode chip 106 to pass through the optical element 104 more uniformly, so as to improve the uniformity of the light of the light emitting diode chip 106. Other technical content, materials, and features of the light emitting diode package structure of the embodiment are described in detail in the above embodiments. Hence, a detailed description thereof is omitted hereinafter.

As described above, in this embodiment, the liquid light emitting diode package structure mat be formed by combining the packaging material layer with the filling material not dissolvable to the packaging material layer, wherein the packaging material layer is formed by mixing the stable and heat-resistant liquid with high viscosity with solid particles, so as to improve the problem of poor heat resistance that occurs in the conventional packaging material and further enhance the reliability of the light emitting diode light source module.

FIGS. 6A and 6B illustrate a schematic cross-sectional view and a partial top view of a light emitting diode package structure according to an embodiment of the disclosure. In FIGS. 6A and 6B, identical reference numerals are used for the same elements as those in FIG. 1, and descriptions of those elements are omitted.

Referring to FIGS. 6A and 6B, a light emitting diode package structure 60 includes a substrate 210, a seal assembly 202, an optical element 234, at least one light emitting diode chip 106, a packaging material layer 108, and a filling material 110. Herein, the optical element 234 is disposed on the seal assembly 202, and an enclosed space S is formed between the optical element 234, the seal assembly 202, and the substrate 210.

In this embodiment, the substrate 210 is a heat dissipation substrate, and a material thereof is copper, for example. However, the disclosure is not limited thereto. In addition, a shape of the substrate 210 shown in FIG. 6A is merely an example; in fact, the shape of the substrate 210 is not particularly limited.

As shown in FIG. 6A, the optical element 234 is a curved convex concave lens, for example. However, persons having ordinary skill in the art should know that the disclosure is not limited thereto, and the optical element 234 may have other shapes.

Moreover, the seal assembly 202 of this embodiment is a mechanism formed by plastic injection. For example, the seal assembly 202 may be consisted of an L-shaped positioning mechanism 202a and a covering mechanism 202b. The L-shaped positioning mechanism 202a is for mechanically positioning the optical element 234 and the seal assembly 202. The covering mechanism 202b covers a sidewall of the substrate 210 during the plastic injection and is combined with the substrate 210. However, the seal assembly 202 may be one single component or be composed of multiple components as required, as long as the optical element 234, the seal assembly 202, and the substrate 210 form the enclosed space S. The disclosure does not limit the number of the components that form the seal assembly 202.

It should be noted that, in this embodiment, the substrate 210 has a groove 210a, and the light emitting diode chip 106 is disposed in the groove 210a. Moreover, the packaging material layer 108 is disposed in the groove 210a and fills the groove 210a. The filling material 110 is disposed in the enclosed space S and fills the enclosed space S.

Herein, the length WA and width WB of the groove 210a are 1-1.5 times the length Wa and width Wb of the light emitting diode chip 106. For example, the length Wa and width Wb of the light emitting diode chip 106 are 1 mm respectively, and the length WA and width WB of the groove 210a are 1-1.5 mm respectively.

Furthermore, as shown in FIG. 6B, the filling material 110 and the optical element 234 of the light emitting diode package structure in this embodiment may also be formed of the same material (such as silicone), and the light emitting diode package structure may be an integral structure formed by mold injection (not shown). That is, in this embodiment, silicone is used as the material of the optical element 234 and the filling material 110 in the enclosed space S, so as to form the light emitting diode package structure. In addition, as described above, the heat dissipation substrate may have various shapes, such as the substrate 230 shown in FIG. 6B.

According to this embodiment, the heat dissipation substrate may be used to improve heat dissipation efficiency, so as to further enhance the reliability of the light emitting diode light source module. Other technical content, materials, and features of the light emitting diode package structure of the disclosure are described in detail in the above embodiments. Hence, a detailed description thereof is omitted hereinafter.

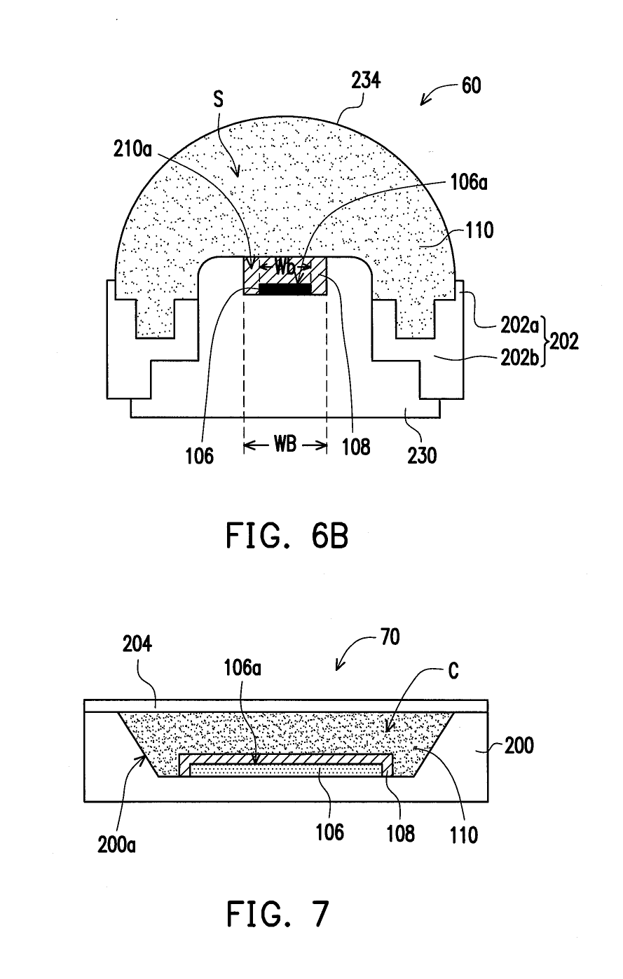

FIG. 7 is a schematic cross-sectional view of a light emitting diode package structure according to an embodiment of the disclosure. In FIG. 7, identical reference numerals are used for the same elements as those in FIG. 1, and descriptions of those elements are omitted.

Referring to FIG. 7, a light emitting diode package structure 70 of the disclosure includes a substrate 200, an optical element 204, at least one light emitting diode chip 106, a packaging material layer 108, and a filling material 110.

The substrate 200 has a groove 200a, and the light emitting diode chip 106 is disposed on the substrate 200 and located in the groove 200a. The optical element 204 is disposed on the substrate 200 and encloses the groove 200a, so as to form an enclosed space C between the optical element 204 and the substrate 200. The optical element 204 shown in FIG. 7 is for example in a planar plate shape and is disposed on the seal assembly 102 to form the enclosed space C. However, the disclosure is not limited thereto. In other embodiments, the optical element 204 may have other shapes, such as the optical element 104 with the curved convex surface 104a in FIG. 1.

The packaging material layer 108 is located in the enclosed space C and disposed on the upper surface 106a of the light emitting diode chip 106 to cover all exposed surfaces of the light emitting diode chip 106. Specifically, the packaging material layer 108 includes a liquid with high viscosity and a plurality of solid particles, and the viscosity of the liquid with high viscosity is more than 3000 mPa·s. Herein, the solid particles are phosphor, TiO₂, ZrO₂, or Quantum Dot (QD), for example. The liquid with high viscosity is for example at least one selected from silicon oil, paraffin oil, olive oil, propylene carbonate, and perfluoropolyether solution.

In addition, the light emitting diode package structure of this embodiment further includes a filling material 110 that fills the enclosed space C. The filling material 110 is a liquid with favorable thermal conductivity, which is more than 0.55 W/m·K, for example. Moreover, the filling material 110 is preferably fluid at room temperature, and the viscosity of the filling material 110 is less than the viscosity of the packaging material layer 108. Specifically, the filling material 110 is deionized water, electrolyzed water, or Fluorinert, for example. However, the disclosure is not limited thereto, and the filling material 110 can be silicone or epoxy resin, for example.

The light emitting diode package structure of this embodiment may selectively include a diffusion layer (not shown) disposed in the enclosed space C and located on a light emitting path of the light emitting diode chip 106. A material of the diffusion layer 112 is nanoparticles of TiO₂, for example, but the disclosure is not limited thereto. The diffusion layer 112 may be disposed to diffuse the light emitted from the light emitting diode chip 106 to pass through the optical element 204 more uniformly, so as to improve the uniformity of the light of the light emitting diode chip 106.

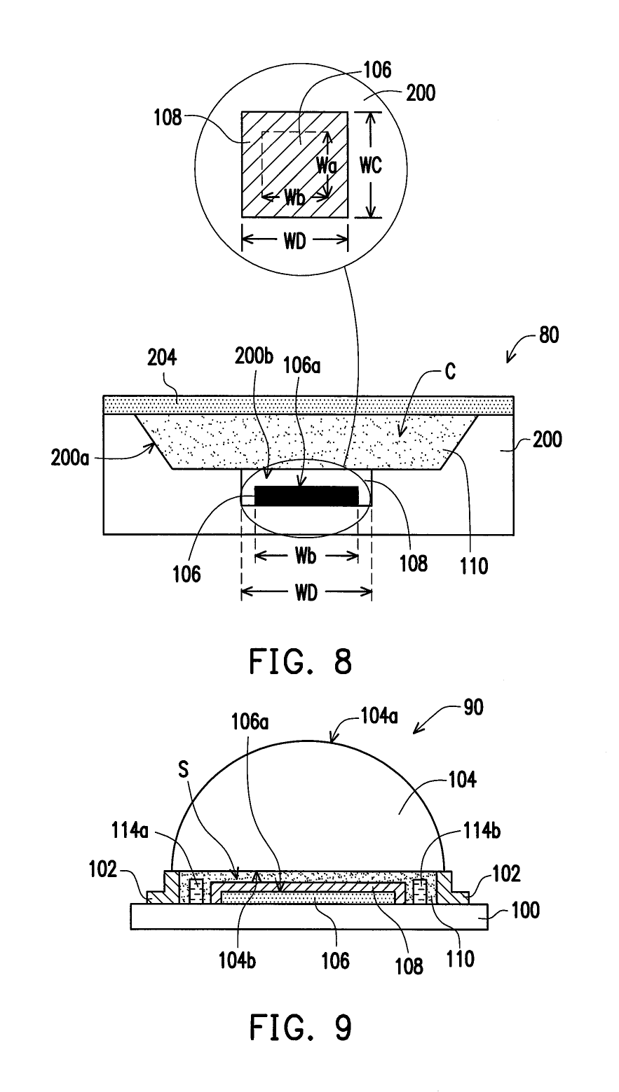

FIG. 8 illustrates a schematic cross-sectional view and a partial top view of a light emitting diode package structure according to an embodiment of the disclosure. In FIG. 8, identical reference numerals are used for the same elements as those in FIG. 7, and descriptions of those elements are omitted.

Referring to FIG. 8, a light emitting diode package structure 80 of the disclosure includes a substrate 200, an optical element 204, at least one light emitting diode chip 106, a packaging material layer 108, and a filling material 110.

A difference between the light emitting diode package structure 80 of this embodiment and the light emitting diode package structure 70 of FIG. 7 lies in that: the groove 200a has a recess 200b, and the light emitting diode chip 106 is disposed in the recess 200b, wherein the length WC and width WD of the recess 200b are 1-1.5 times the length Wa and width Wb of the light emitting diode chip 106 respectively.

For example, the length WC and width WD of the recess 200b are 1 mm respectively, and the length Wa and width Wb of the light emitting diode chip 106 are 1-1.5 mm respectively. In addition, the packaging material layer is disposed in the recess 200b and fills the recess 200b. The filling material 110 is disposed in the enclosed space C and fills the enclosed space C.

Other technical content, materials, and features of the light emitting diode package structure of this embodiment are described in detail in the above embodiments.

It is worth mentioning that, although in the embodiments of FIGS. 7-8, the packaging material layer 108 is used to cover all exposed surfaces of the light emitting diode chip 106, and the filling material 110 is used to fill the enclosed space C, for example, the disclosure is not limited thereto. In other embodiments, the substrate 200 with the groove 200a depicted in FIG. 7 or the substrate 200 with the recess 200b depicted in FIG. 8 may be combined with any of the liquid packaging methods described in the above embodiments (shown in FIGS. 1-6B) to complete the light emitting diode package structure of the disclosure. Persons with ordinary skill in the art are able to understand application and variation of the disclosure based on the above embodiments, and thus relevant descriptions will be omitted hereinafter.

FIG. 9 is a schematic cross-sectional view of a light emitting diode package structure according to an embodiment of the disclosure. In FIG. 9, identical reference numerals are used for the same elements as those in FIG. 1, and descriptions of those elements are omitted.

Referring to FIG. 9, a light emitting diode package structure 90 of the disclosure includes a substrate 100, an optical element 104, at least one light emitting diode chip 106, a packaging material layer 108, and a filling material 110.

It should be noted that, the light emitting diode package structure 90 of this embodiment is similar to the light emitting diode package structure 10 of FIG. 1, and a difference lies in that: the light emitting diode package structure 90 of this embodiment further includes an electrode 114a and an electrode 114b which are for example disposed on the substrate 100 and located in the enclosed space S, as shown in FIG. 9. It is worth noting that, in this embodiment, a voltage may be applied to the electrodes 114a and 114b from outside of the light emitting diode package structure through an electrowetting technique, so as to form an electric field, thereby changing a contact angle of the packaging material layer 108 and the filling material 110 to control a light emitting angle of the light emitting diode and achieve a variable lighting pattern light emitting diode.

Furthermore, although in the embodiment of FIG. 9, two independent electrodes are added to the light emitting diode package structure 10 of FIG. 1, for example; the disclosure, however, is not limited thereto. The independent electrodes may be added to any of the configurations of the above embodiments (e.g. FIGS. 1-8) for carrying out the electrowetting technique, so as to complete the light emitting diode package structure of the disclosure. Persons with ordinary skill in the art are able to understand application and variation of the disclosure based on the above embodiments, and thus relevant descriptions will be omitted hereinafter.

To conclude the above, by mixing the stable and heat-resistant liquid with high viscosity and solid particles in the packaging material layer and selectively using the filling material that is not dissolvable to the packaging material layer, the light emitting diode package structure of the disclosure may be formed with better stability and heat resistance. More specifically, the packaging material layer used in the light emitting diode package structure of the disclosure is not cured when heated and provides better stability that increases the stability of the light source module. Therefore, even if the packaging material layer is applied to a high-power light emitting diode chip, the conventional problem of poor heat resistance that occurs when phosphor is used as the packaging material can be prevented, and accordingly the reliability of the light emitting diode light source module is further enhanced.

It will be apparent to those skilled in the art that various modifications and variations can be made to the disclosed embodiments without departing from the scope or spirit of the disclosure. In view of the foregoing, it is intended that the disclosure covers modifications and variations of this disclosure provided that they fall within the scope of the following claims and their equivalents.

What is claimed is:

1. A light emitting diode package structure, comprising:
a substrate;
a seal assembly disposed on the substrate;
an optical element disposed on the seal assembly, wherein an enclosed space is formed between the optical element, the seal assembly, and the substrate;
at least one light emitting diode chip disposed on the substrate and located in the enclosed space; and
a packaging material layer located in the enclosed space and at least disposed on an upper surface of the light emitting diode chip, wherein the packaging material layer comprises a liquid with high viscosity and a plurality of solid particles, and the viscosity of the liquid with high viscosity is more than 3000 mPa·s.

2. The light emitting diode package structure of claim 1, wherein the solid particles comprise phosphor, TiO₂, ZrO₂, or Quantum Dot (QD).

3. The light emitting diode package structure of claim 1, wherein the liquid with high viscosity is at least one selected from silicon oil, paraffin oil, olive oil, propylene carbonate, and perfluoropolyether solution.

4. The light emitting diode package structure of claim 1, wherein the packaging material layer covers the light emitting diode chip and fills the enclosed space.

5. The light emitting diode package structure of claim 1, further comprising a filling material disposed in the enclosed space, wherein the viscosity of the filling material is less than the viscosity of the packaging material layer.

6. The light emitting diode package structure of claim 5, wherein the packaging material layer covers all exposed surfaces of the light emitting diode chip, and the filling material fills the enclosed space.

7. The light emitting diode package structure of claim 5, wherein the packaging material layer is disposed on a plane of the optical element, and the filling material is disposed between the packaging material layer and the light emitting diode chip.

8. The light emitting diode package structure of claim 5, wherein the packaging material layer covers only the upper surface of the light emitting diode chip, and the filling material fills the enclosed space.

9. The light emitting diode package structure of claim 5, wherein the thermal conductivity of the filling material is more than 0.55 W/m·K.

10. The light emitting diode package structure of claim 5, wherein the filling material comprises deionized water, electrolyzed water, Fluorinert, air, silicone, or epoxy resin.

11. The light emitting diode package structure of claim 1, further comprising a diffusion layer disposed in the enclosed space and located on a light emitting path of the light emitting diode chip.

12. The light emitting diode package structure of claim 11, wherein a material of the diffusion layer comprises nanoparticles of TiO₂.

13. The light emitting diode package structure of claim 1, wherein the optical element comprises a curved convex surface and a plane, and the plane is disposed on the seal assembly and faces the substrate.

14. The light emitting diode package structure of claim 1, wherein the optical element is in a planar plate shape.

15. The light emitting diode package structure of claim 1, further comprising two electrodes disposed on the substrate and located in the enclosed space.

16. The light emitting diode package structure of claim 1, wherein the substrate comprises a groove, and the light emitting diode chip is disposed in the groove, wherein the length and width of the groove are 1-1.5 times the length and width of the light emitting diode chip respectively.

17. The light emitting diode package structure of claim 16, wherein the packaging material layer is disposed in the groove.

18. The light emitting diode package structure of claim 17, further comprising a filling material disposed in the enclosed space, wherein the viscosity of the filling material is less than the viscosity of the packaging material layer.

19. The light emitting diode package structure of claim 17, wherein the filling material fills the enclosed space.

20. A light emitting diode package structure, comprising:
a substrate comprising a groove;
at least one light emitting diode chip disposed on the substrate and located in the groove;
an optical element disposed on the substrate and enclosing the groove to form an enclosed space between the optical element and the substrate; and
a packaging material layer located in the enclosed space and at least disposed on an upper surface of the light emitting diode chip, wherein the packaging material layer comprises a liquid with high viscosity and a plurality of solid particles, and the viscosity of the liquid with high viscosity is more than 3000 mPa·s.

21. The light emitting diode package structure of claim 20, wherein the solid particles comprise phosphor, TiO₂, ZrO₂, or Quantum Dot (QD).

22. The light emitting diode package structure of claim 20, wherein the liquid with high viscosity is at least one selected from silicon oil, paraffin oil, olive oil, propylene carbonate, and perfluoropolyether solution.

23. The light emitting diode package structure of claim 20, wherein the groove comprises a recess, and the light emitting diode chip is located in the recess, wherein the length and width of the recess are 1-1.5 times the length and width of the light emitting diode chip respectively.

24. The light emitting diode package structure of claim 20, wherein the packaging material layer is disposed in the recess.

25. The light emitting diode package structure of claim 20, further comprising a filling material disposed in the enclosed space, wherein the viscosity of the filling material is less than the viscosity of the packaging material layer.

26. The light emitting diode package structure of claim 23, wherein the filling material fills the enclosed space.

27. The light emitting diode package structure of claim 25, wherein the thermal conductivity of the filling material is more than 0.55 W/m·K.

28. The light emitting diode package structure of claim 25, wherein the filling material comprises deionized water, electrolyzed water, Fluorinert, air, silicone, or epoxy resin.

29. The light emitting diode package structure of claim 20, further comprising a diffusion layer disposed in the enclosed space and located on a light emitting path of the light emitting diode chip.

30. The light emitting diode package structure of claim 20, wherein a material of the diffusion layer comprises nanoparticles of TiO₂.
